(19) United States
(12) Patent Application Publication
(10) Pub. No.: US 2026/0214880 A1
(43) Pub. Date: Jul. 23, 2026

(54) Memory Circuitry And Methods Used In Forming Memory Circuitry

(71) Applicant: Micron Technology, Inc., Boise, ID (US)

(72) Inventors: Adriel Jebin Jacob Jebaraj, Meridian, ID (US); Christopher J. Gambee, Caldwell, ID (US); Ruijing Ge, Boise, ID (US)

(73) Assignee: Micron Technology, Inc., Boise, ID (US)

(21) Appl. No.: 19/061,116

(22) Filed: Feb. 24, 2025

Related U.S. Application Data
(60) Provisional application No. 63/747,144, filed on Jan. 20, 2025.

(51) Int. Cl. H10B 12/00

(52) U.S. Cl. CPC H10B 12/30; H10B 12/05

(57) ABSTRACT

Memory circuitry comprises vertically alternating insulative tiers and memory-cell tiers. Memory cells in the memory-cell tiers individually comprise a horizontal transistor and a capacitor electrically coupled therewith. Immediately-x-direction-adjacent channel regions of the transistors that are in the same memory-cell tier have facing z-direction sides that oppose one another in the x-direction. Insulating material is horizontally between the immediately-x-direction-adjacent channel regions. The insulating material is directly against the z-direction sides of the immediately-x-direction-adjacent channel regions and extends horizontally continuously there-between along the x-direction. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z-direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-11 are diagrammatic sectional views of constructions in accordance with embodiments of the invention.

FIGS. 12-20 are diagrammatic sequential sectional and/or enlarged views of the construction of FIGS. 3-9, or portions thereof or alternate and/or additional embodiments, in process in accordance with some embodiments of the invention.

### DETAILED DESCRIPTION OF EXAMPLE EMBODIMENTS

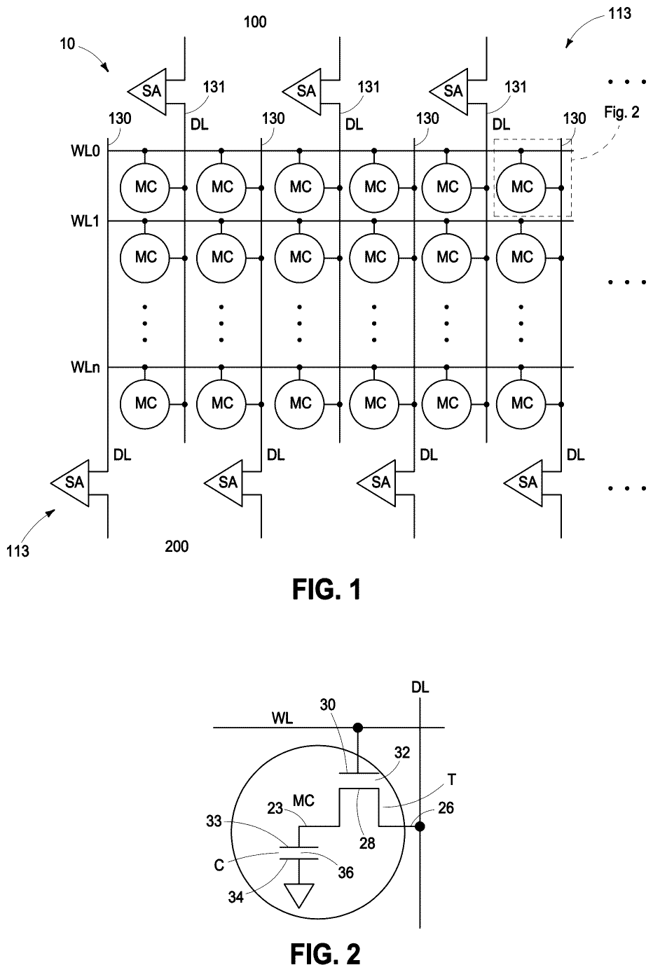

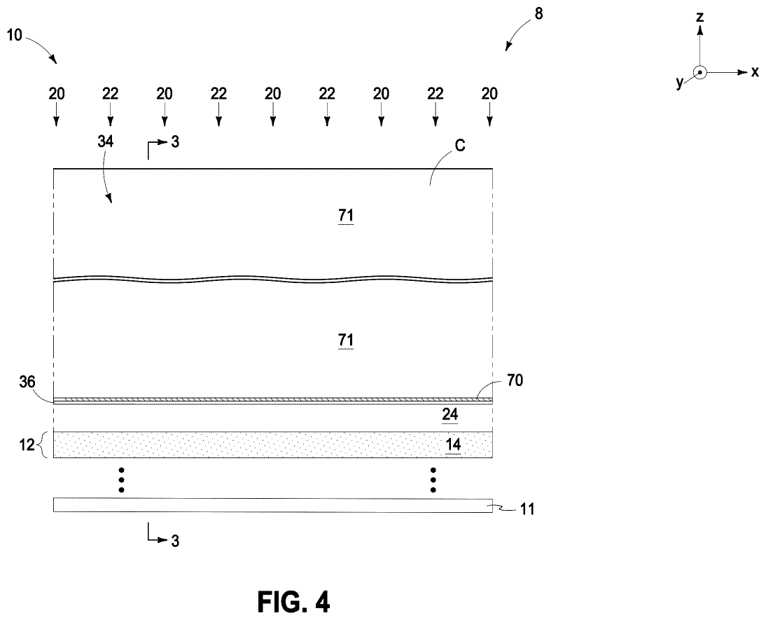

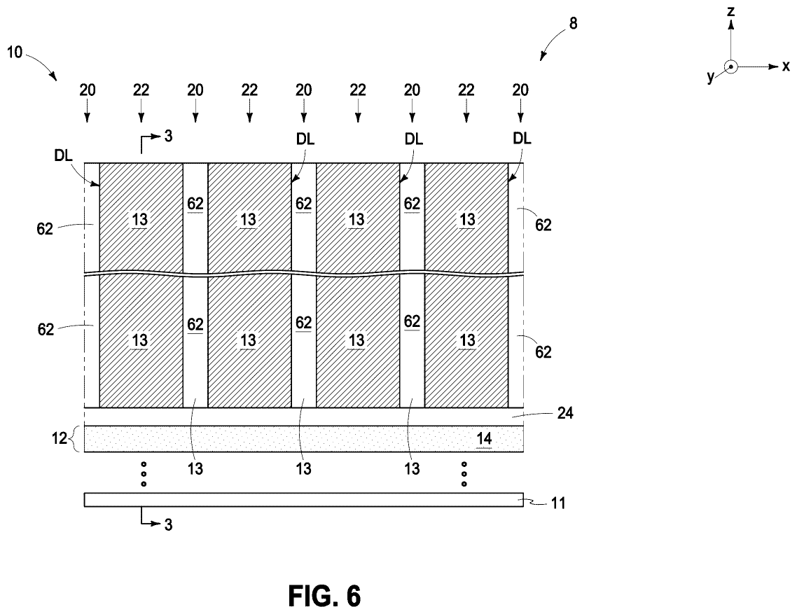

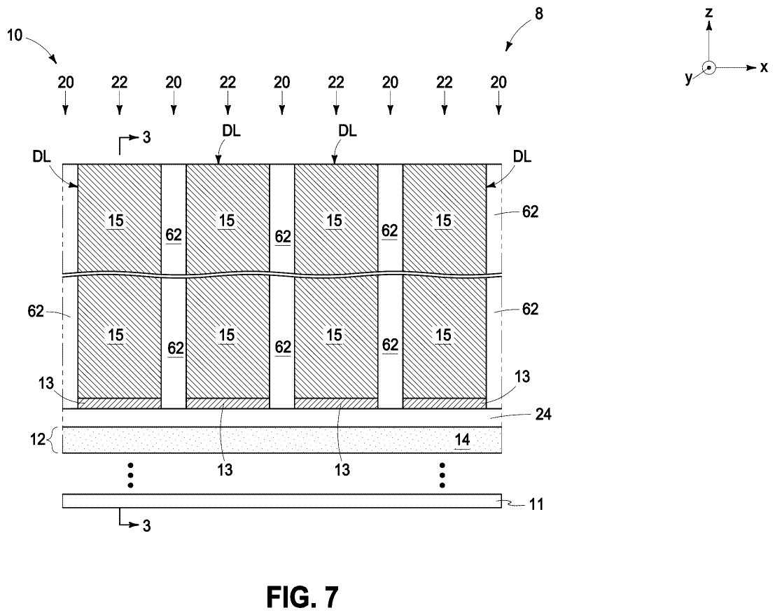

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-11.

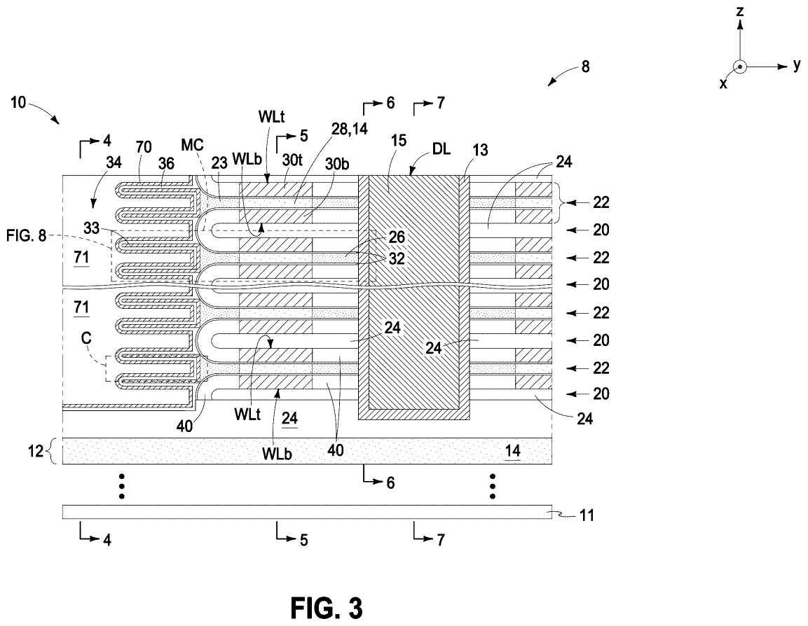

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-9, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-9-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

Example memory circuitry (e.g., that of or comprising construction 8) comprises vertically-alternating insulative tiers 20 and memory-cell tiers 22 above semiconductor material 14. Example memory-cell tiers 22 comprise memory cells MC and example insulative tiers 20 comprise insulative material 24 (e.g., silicon dioxide). Memory cells MC individually comprise a horizontal transistor T and a capacitor C electrically coupled (e.g., directly) therewith. Horizontal transistor T comprises a gate 30* (e.g., conductive metal material) that is part of one of a plurality of horizontal conductive access lines WL* that individually directly electrically couple together multiple of gates 30* of different ones of horizontal transistors T that are in the same memory-cell tier 22 (an * being used as a suffix to be inclusive of all such same-numerically-designated structures or portions thereof that may or may not have other suffixes). Gate 30* comprises a top gate 30t and a bottom gate 30 b having a channel region 28 vertically there-between. Top gate 30t is part of one of a plurality of top horizontal access lines WLt and bottom gate 30b is part of one of a plurality of bottom horizontal access lines WLb. Individual top and bottom access lines WLt and WLb, respectively, are horizontally elongated in a horizontal x-direction and are laterally spaced from one another in horizontal y-direction that is orthogonal to the first direction. Insulative material 24 of insulative tiers 20 is vertically between top access line WLt and bottom access line WLb of immediately-vertically-adjacent the memory-cell tiers 22 (there being no other such noun [tier] between those that are immediately-adjacent one another). The y-direction lengths of conductive access lines WLt and WLb are diagrammatic. Such may be of equal or different lengths relative one another than is shown and/or may or may not be centered in the y-direction (with channel region 28) between the capacitors and transistors.

Example horizontal transistor T comprises a first source/drain region 23 (e.g., conductively-doped silicon), a second source/drain region 26 (e.g., conductively-doped silicon), with channel region 28 being horizontally there-between. The y-direction lengths of regions 23, 26, and 28 are diagrammatic in the figures. Such may be of equal or different lengths relative one another than is shown. Regions 23 and 26 of different immediately-horizontally-adjacent memory cells MC into and out of the plane of the page upon which FIG. 3 lies in a common memory-cell tier 22 (e.g., in the x-direction) may be isolated relative one another by insulative material (not shown). A gate insulator 32 (e.g., dielectric or ferroelectric) is vertically between each of the respective top and bottom gates 30t and 30b and channel region 28. An example insulator material 40 (e.g., silicon nitride) is laterally against lateral sides/edges of gates 30*.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material (e.g., conductively-doped epitaxial silicon and not shown) may be between storage-node electrode 33 and first source/drain region 23 (e.g., and such may be considered as a part of either or both).

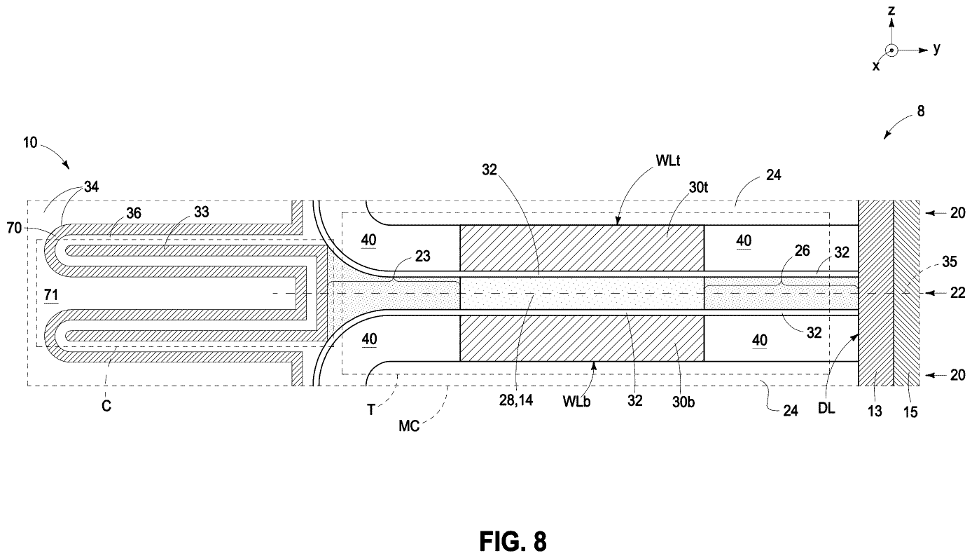

Digitlines DL (e.g., comprising conductive materials 13 and 15) extend through vertically-alternating tiers 20 and 22. Conductively-doped semiconductive material (not shown) may be between/proximate digitline DL and second source/drain region 26. Digitlines DL of different immediately-horizontally-adjacent memory cells MC running into and out of the plane of the page upon which FIG. 3 lies (in the x-direction) may be isolated/spaced relative one another by insulative material 62 (e.g., silicon dioxide and/or silicon nitride). Individual second source/drain regions 26 of individual transistors T that are in different memory-cell tiers 22 are electrically coupled (e.g., directly electrically coupled) to individual digitlines DL. Capacitor C and horizontal transistor T may be considered as being horizontally spaced relative one another along horizontal axis 35 (FIG. 8) along the y-direction.

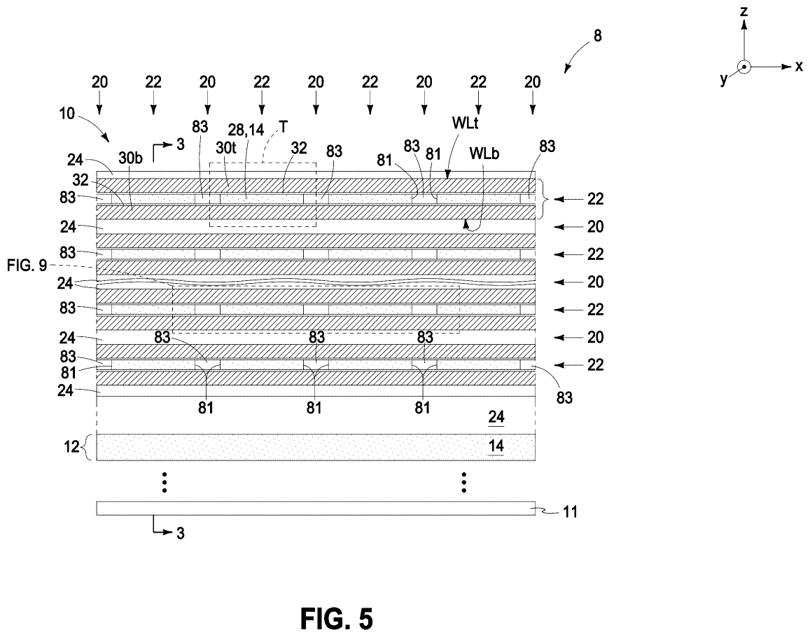

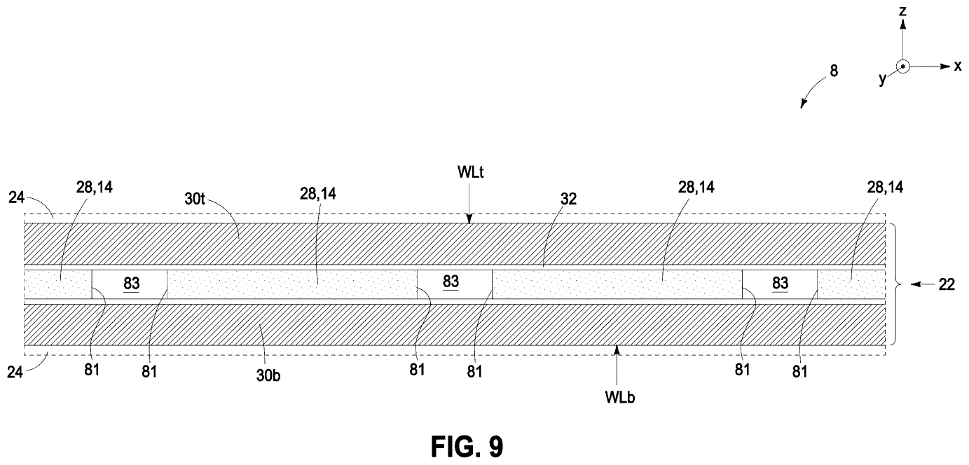

Immediately-x-direction-adjacent channel regions 28 that are in the same memory-cell tier 22 have facing z-direction sides 81 that oppose one another in the x-direction (FIGS. 5 and 9). Insulating material 83 (e.g., silicon dioxide and/or silicon nitride) is horizontally between immediately-x-direction-adjacent channel regions 28. Insulating material 83 is directly against z-direction sides 81 of immediately-x-direction-adjacent channel regions 28 and extends horizontally continuously there-between along the x-direction. In one embodiment, at least a portion of each of z-direction sides 81 (all as shown) extends exactly vertically. Alternately, no portion of each of z-direction sides 81 extends exactly vertically (not shown). Some or all of z-directions sides 81 could be curved, straight, or a combination of different curved and/or straight segments.

In one embodiment and as shown, gate insulator 32 is directly against top and bottom surfaces of insulating material 83. In one such embodiment, gate insulator 32 is directly against top and bottom surfaces of channel region 28, with gate insulator 32 that is directly against the top surface of channel region 28 extending horizontally continuously between immediately-x-direction-adjacent channel regions 28 and gate insulator 32 that is directly against the bottom surface of channel region 28 extends horizontally continuously between immediately-x-direction-adjacent channel regions 28. In one embodiment and as shown, top and bottom surfaces of individual top and bottom access lines WLt and WLb are everywhere horizontally planar over and between immediately-x-direction-adjacent channel regions 28.

Any other attribute(s) or aspect(s) as shown and/or described herein with respect to other embodiments may be used in the embodiments shown and described with reference to the above embodiments.

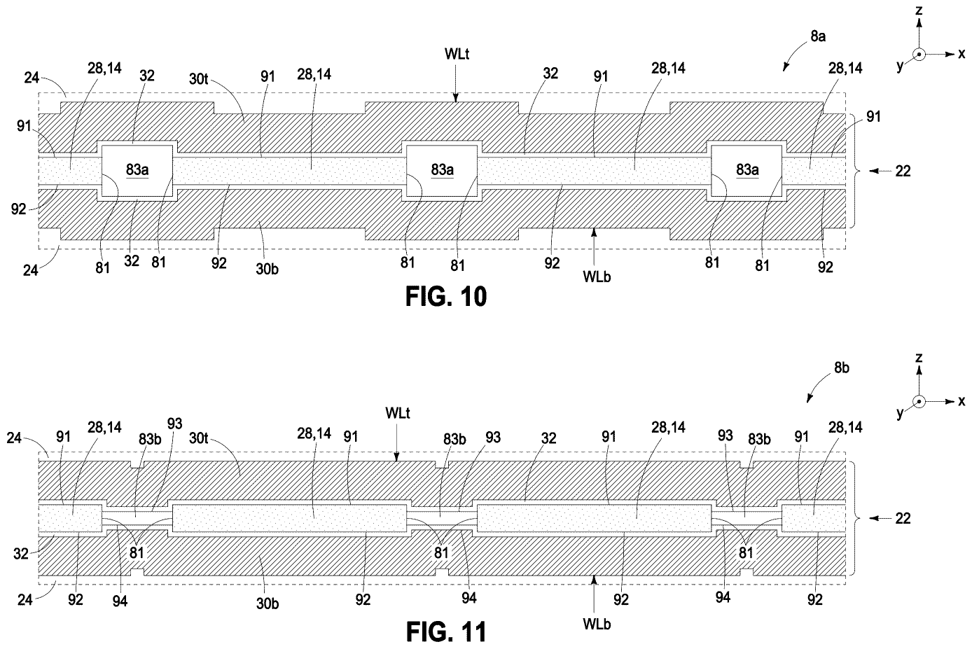

An alternate construction 8a (corresponding in position and scale to that of FIG. 9) is shown in FIG. 10. Like numerals from the above-described embodiments have been used where appropriate, with some construction differences being indicated with the suffix “a” or with different numerals. In one embodiment and as shown, insulating material 83a where horizontally between immediately-x-direction-adjacent channel regions 28 projects upwardly relative to a top surface 91 of immediately-x-direction-adjacent channel regions 28. In one embodiment and as shown, insulating material 83a where horizontally between immediately-x-direction-adjacent channel regions 28 projects downwardly relative to a bottom surface 92 of immediately-x-direction-adjacent channel regions 28. Any other attribute(s) or aspect(s) as shown and/or described herein with respect to other embodiments may be used.

An alternate construction 8b (corresponding in position and scale to that of FIGS. 9 and 10) is shown in FIG. 11. Like numerals from the above-described embodiments have been used where appropriate, with some construction differences being indicated with the suffix “b” or with different numerals. In one embodiment and as shown, insulating material 83b where horizontally between immediately-x-direction-adjacent channel regions 28 has a top surface 93 that is lower than a top surface 91 of immediately-x-direction-adjacent channel regions 28. In one embodiment and as shown, insulating material 83b where horizontally between immediately-x-direction-adjacent channel regions 28 has a bottom surface 94 that is higher than a bottom surface 92 of immediately-x-direction-adjacent channel regions 28. Any other attribute(s) or aspect(s) as shown and/or described herein with respect to other embodiments may be used.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

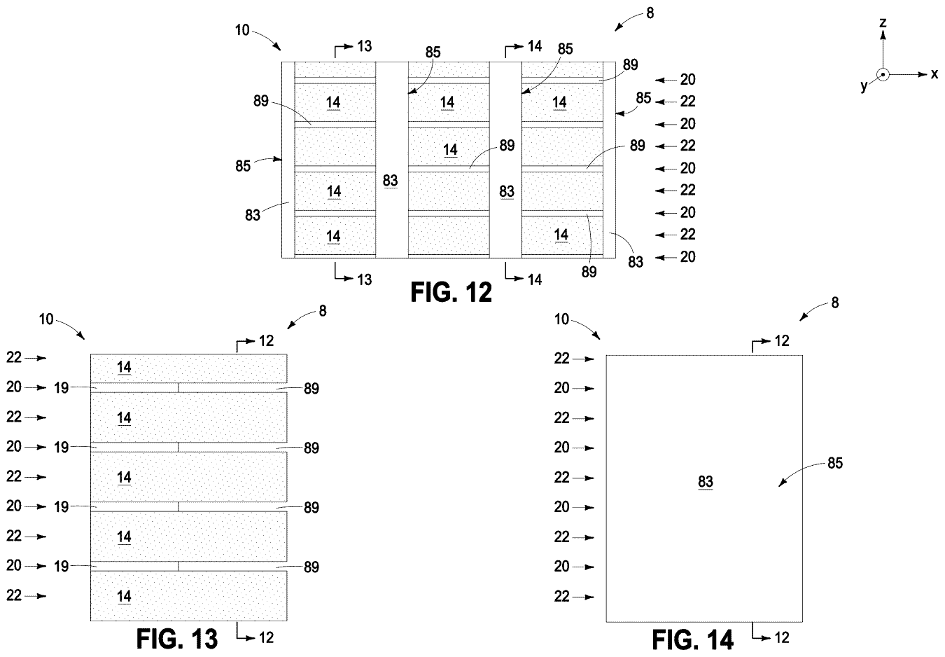

FIGS. 12-20 by way of example sequentially show predecessor constructions in an example method used in forming memory circuitry in accordance with embodiments of the invention. Such memory circuitry ultimately comprises vertically-stacked memory cells individually comprising a horizontal transistor and a capacitor electrically coupled (e.g., directly) therewith. Such memory circuitry may comprise structural embodiments of the invention as described above with respect to FIGS. 3-11.

Referring to FIGS. 12-14, vertically-alternating insulative tiers 20 and memory-cell tiers 22 have been formed. Memory cells (not-yet-shown) of memory-cell tiers 22 individually comprise a horizontal transistor (not-yet-shown) and a capacitor (not-yet-shown) in a finished-circuitry construction (not-yet-shown). Memory-cell tiers 22 comprise channel material 14 (lightly doped or undoped silicon) of individual channel regions 28 of individual of the horizontal transistors being formed. A material 19 (e.g., SiGe) of different composition from that of channel material 14 is in insulative tiers 20. Insulating walls 85 comprising insulating material 83 extend vertically through vertically-alternating insulative and memory-cell tiers 20, 22 and separate channel material 14 into individual channel regions 28 along a horizontal x-direction. Void-spaces 89 are in insulative tiers 20 and individually extend horizontally along the x-direction between immediately-x-direction-adjacent insulating walls 85 and separate channel material 14 vertically.

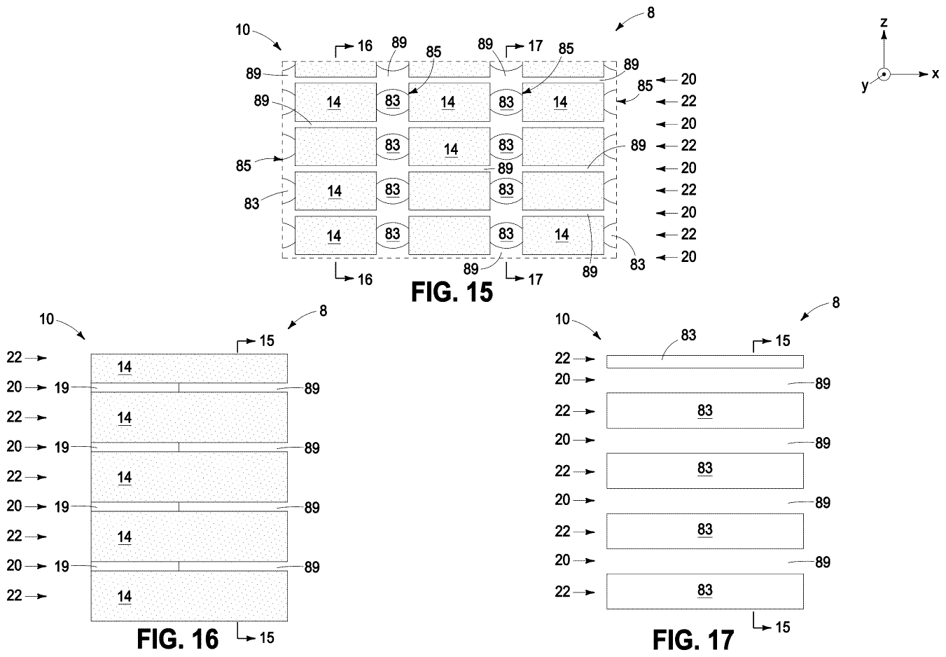

Referring to FIGS. 15-17, through void-spaces 89, lateral etching has been conducted through insulating material 83 of insulating walls 85 in individual insulative tiers 20 to extend void-spaces 89 laterally through insulating walls 85 (e.g., ideally selectively relative to channel material 14 as shown). As shown, such may etch more of insulating material 83 that is proximate channel material 14 (in the x-direction) than is distal (e.g., central) there-from. As an example, and by way of example only, where insulating material 83 is silicon dioxide and channel material 14 is silicon, an HF solution may be used as a liquid etching fluid (e.g., 100:1 to 500:1 [water:49% HF] by volume, 0° C. to 80° C., and room pressure). As an alternate example vapor HF and NH₃ may be used as a vapor etching fluid (e.g., 30° C. to 120° C. and 0.1 Torr to 10 Torr pressure).

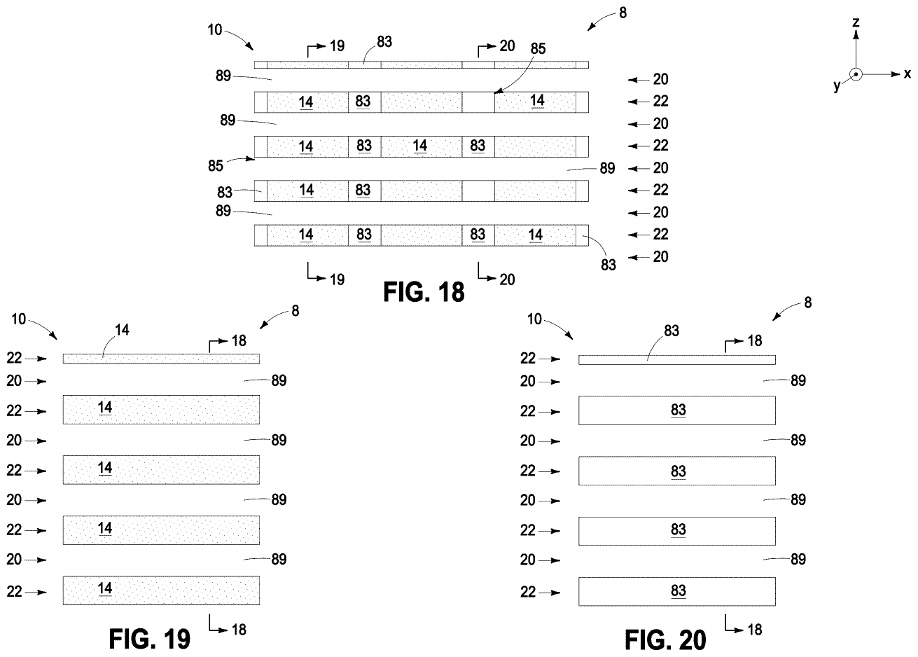

Referring to FIGS. 18-20, through extended void-spaces 89, channel and insulating materials 14 and 83 have been thinned (e.g., by etching). In one embodiment, the channel and insulating materials 14 and 83 are thinned simultaneously at the same rate. Alternately, channel and insulating materials 14, and 83 are thinned simultaneously at different rates (either being faster/slower than the other). In one embodiment, channel and insulating materials 14 and 83 are thinned selectively relative to one another. Where insulating material 83 is silicon dioxide and channel material 14 is silicon, an example etching fluid of ammonia and hydrogen peroxide can be used to simultaneously etch such, with volumetric ratio of ammonia to hydrogen peroxide being varied depending on the desired relative etch rate(s) for each (e.g., more ammonia compared to hydrogen peroxide resulting in greater etch rate of silicon relative to silicon dioxide). FIGS. 18-20 show ultimate thinning of channel and insulating materials 14 and 83 as being to the same degree (regardless of any simultaneity), which will likely result in a finished construction as shown in FIGS. 3-9. Alternately, such may be ultimately thinned (regardless of any simultaneity) to different degrees resulting in a finished construction of either of the constructions shown in FIGS. 10 and 11.

Referring to FIGS. 3-9, and following from FIGS. 18 and 20, top and bottom horizontal access lines WLt and WLb have been formed in memory cell tiers 22 that are respectively directly above and directly below the thinned channel and insulating materials 14, 83 and that are horizontally elongated in the x-direction. Example manners not material to the inventions disclosed herein in forming that which is shown are, for example, shown in Micron Technology's U.S. Patent Application Publication Nos. 2022/0254784, 2022/0130834, U.S. Pat. No. 11,342,218, etc.

Any other attribute(s) or aspect(s) as shown and/or described herein with respect to other embodiments may be used.

Some embodiments of the invention were motivated towards reducing existence or volume of void spaces in the conductive material of access lines WL* that can develop between the gate insulator of immediately-horizontally-adjacent horizontal transistors in the x-direction. Embodiments herein may reduce the existence or volume of such void spaces (e.g., be presence of insulating material 83 which may, although not require, preclude any of the conductive material of access lines WL* from being horizontally between immediately-x-direction-adjacent horizontal transistors between top and bottom surfaces of their top and bottom gate insulator).

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of the vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90°or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming vertically-alternating insulative tiers and memory-cell tiers. Memory cells of the memory-cell tiers individually comprise a horizontal transistor and a capacitor in a finished-circuitry construction. The memory-cell tiers comprise channel material of individual channel regions of individual of the horizontal transistors being formed. Insulating walls extend vertically through the vertically-alternating insulative and memory-cell tiers and separate the channel material into the individual channel regions along a horizontal x-direction. Void-spaces in the insulative tiers individually extend horizontally along the x-direction between immediately-x-direction-adjacent of the insulating walls and separate the channel material vertically. Through the void-spaces, insulating material of the insulating walls is laterally etched through in individual of the insulative tiers to extend the void-spaces laterally through the insulating walls. Through the extended void-spaces, the channel and insulating materials are thinned. Top and bottom horizontal access lines are formed in the memory cell tiers that are respectively directly above and directly below the thinned channel and insulating materials and that are horizontally elongated in the x-direction.

In some embodiments, memory circuitry comprises vertically alternating insulative tiers and memory-cell tiers. Memory cells in the memory-cell tiers individually comprise a horizontal transistor and a capacitor electrically coupled therewith. The horizontal transistor comprises a top gate and a bottom gate having a channel region vertically there-between. The top gate is part of one of a plurality of top horizontal access lines and the bottom gate is part of one of a plurality of bottom horizontal access lines. Individual of the top and bottom access lines are horizontally elongated in a horizontal x-direction. The insulative tiers comprise an insulative material that is vertically between the top access line and the bottom access line of immediately-vertically-adjacent of the memory-cell tiers. Immediately-x-direction-adjacent of the channel regions that are in the same memory-cell tier have facing z-direction sides that oppose one another in the x-direction. Insulating material is horizontally between the immediately-x-direction-adjacent channel regions. The insulating material is directly against the z-direction sides of the immediately-x-direction-adjacent channel regions and extends horizontally continuously there-between along the x-direction.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming vertically-alternating insulative tiers and memory-cell tiers, memory cells of the memory-cell tiers individually comprising a horizontal transistor and a capacitor in a finished-circuitry construction;
the memory-cell tiers comprising channel material of individual channel regions of individual of the horizontal transistors being formed, insulating walls that extend vertically through the vertically-alternating insulative and memory-cell tiers and that separate the channel material into the individual channel regions along a horizontal x-direction, void-spaces in the insulative tiers that individually extend horizontally along the x-direction between immediately-x-direction-adjacent of the insulating walls and that separate the channel material vertically;
through the void-spaces, laterally etching through insulating material of the insulating walls in individual of the insulative tiers to extend the void-spaces laterally through the insulating walls;
through the extended void-spaces, thinning the channel and insulating materials; and
forming top and bottom horizontal access lines in the memory cell tiers that are respectively directly above and directly below the thinned channel and insulating materials and that are horizontally elongated in the x-direction.

2. The method of claim 1 wherein the channel and insulating materials are thinned simultaneously at the same rate.

3. The method of claim 1 wherein the channel and insulating materials are thinned simultaneously at different rates.

4. The method of claim 3 wherein the channel material is thinned faster than the insulating material.

5. The method of claim 3 wherein the insulating material is thinned faster than the channel material.

6. The method of claim 1 wherein the channel and insulating materials are thinned selectively relative to one another.

7. The method of claim 1 wherein the void-spaces before starting the laterally etching are directly against the immediately-x-direction-adjacent insulating walls.

8. The method of claim 1 comprising a gate insulator that is vertically between each of the respective top and bottom access lines and the individual channel regions, the gate insulator being directly against top and bottom surfaces of the insulating material that is horizontally between immediately-x-direction-adjacent of the channel regions.

9. The method of claim 1 wherein the insulating material where horizontally between immediately-x-direction-adjacent of the channel regions in the finished circuitry construction projects upwardly relative to a top surface of the immediately-x-direction-adjacent channel regions.

10. The method of claim 1 wherein the insulating material where horizontally between immediately-x-direction-adjacent of channel regions in the finished circuitry construction projects downwardly relative to a bottom surface of the immediately-x-direction-adjacent channel regions.

11. The method of claim 1 wherein the insulating material where horizontally between immediately-x-direction-adjacent of the channel regions in the finished circuitry construction has a top surface that is lower than a top surface of the immediately-x-direction-adjacent channel regions.

12. The method of claim 1 wherein the insulating material where horizontally between immediately-x-direction-adjacent of the channel regions in the finished circuitry construction has a bottom surface that is higher than a bottom surface of the immediately-x-direction-adjacent channel regions.

13. Memory circuitry comprising:
vertically alternating insulative tiers and memory-cell tiers;
memory cells in the memory-cell tiers that individually comprise a horizontal transistor and a capacitor electrically coupled therewith, the horizontal transistor comprising a top gate and a bottom gate having a channel region vertically there-between, the top gate being part of one of a plurality of top horizontal access lines and the bottom gate being part of one of a plurality of bottom horizontal access lines, individual of the top and bottom access lines being horizontally elongated in a horizontal x-direction;
the insulative tiers comprising an insulative material that is vertically between the top access line and the bottom access line of immediately-vertically-adjacent of the memory-cell tiers; and
immediately-x-direction-adjacent of the channel regions that are in the same memory-cell tier having facing z-direction sides that oppose one another in the x-direction, insulating material that is horizontally between the immediately-x-direction-adjacent channel regions, the insulating material being directly against the z-direction sides of the immediately-x-direction-adjacent channel regions and that extends horizontally continuously there-between along the x-direction.

14. The memory circuitry of claim 13 wherein at least a portion of each of the z-direction sides extends exactly vertically.

15. The memory circuitry of claim 14 wherein all of each of the z-direction sides extends exactly vertically.

16. The memory circuitry of claim 13 wherein the horizontal transistor comprises a gate insulator vertically between each of the respective top and bottom gates and the channel region, the gate insulator being directly against top and bottom surfaces of the insulating material that is horizontally between the immediately-x-direction-adjacent channel regions.

17. The memory circuitry of claim 16 wherein the gate insulator is directly against top and bottom surfaces of the channel region, the gate insulator that is directly against the top surface of the channel region extending horizontally continuously between the immediately-x-direction-adjacent channel regions, the gate insulator that is directly against the bottom surface of the channel region extending horizontally continuously between the immediately-x-direction-adjacent channel regions.

18. The memory circuitry of claim 17 wherein at least a portion of each of the z-direction sides extends exactly vertically.

19. The memory circuitry of claim 13 wherein top and bottom surfaces of the individual top and bottom access lines are everywhere horizontally planar over and between the immediately-x-direction-adjacent channel regions.

20. The memory circuitry of claim 13 wherein the insulating material where horizontally between the immediately-x-direction-adjacent channel regions projects upwardly relative to a top surface of the immediately-x-direction-adjacent channel regions.

21. The memory circuitry of claim 13 wherein the insulating material where horizontally between the immediately-x-direction-adjacent channel regions projects downwardly relative to a bottom surface of the immediately-x-direction-adjacent channel regions.

22. The memory circuitry of claim 13 wherein,
the insulating material where horizontally between the immediately-x-direction-adjacent channel regions projects upwardly relative to a top surface of the immediately-x-direction-adjacent channel regions; and
the insulating material where horizontally between the immediately-x-direction-adjacent channel regions projects downwardly relative to a bottom surface of the immediately-x-direction-adjacent channel regions.

23. The memory circuitry of claim 13 wherein the insulating material where horizontally between the immediately-x-direction-adjacent channel regions has a top surface that is lower than a top surface of the immediately-x-direction-adjacent channel regions.

24. The memory circuitry of claim 13 wherein the insulating material where horizontally between the immediately-x-direction-adjacent channel regions has a bottom surface that is higher than a bottom surface of the immediately-x-direction-adjacent channel regions.

25. The memory circuitry of claim 13 wherein,
the insulating material where horizontally between the immediately-x-direction-adjacent channel regions has a top surface that is lower than a top surface of the immediately-x-direction-adjacent channel regions; and
the insulating material where horizontally between the immediately-x-direction-adjacent channel regions has a bottom surface that is higher than a bottom surface of the immediately-x-direction-adjacent channel regions.
